(19) United States
(12) Patent Application Publication
(10) Pub. No.: US 2025/0221250 A1
(43) Pub. Date: Jul. 3, 2025

(54) DISPLAY DEVICE

(71) Applicant: LG Display Co., Ltd., Seoul (KR)

(72) Inventors: SungSik SON, Gumi-si (KR); SangMoo SONG, Seoul (KR); JuHan KIM, Daegu (KR)

(21) Appl. No.: 18/800,864

(22) Filed: Aug. 12, 2024

(30) Foreign Application Priority Data
Dec. 29, 2023 (KR) 10-2023-0197081

(51) Int. Cl. H10K 59/80; H10K 50/19

(52) U.S. Cl. CPC H10K 59/8722; H10K 50/19; H10K 59/8794

(57) ABSTRACT

Provided is a display device. The display device includes a display panel including a light transmission area having subpixels for displaying image, a backplate disposed below the display panel, a protective layer disposed below the backplate, a heat dissipation sheet disposed below the protective layer, and an optical device disposed below the display panel and configured to overlap the light transmission area, in which the protective layer and the heat dissipation sheet respectively include openings that overlap the light transmission area. Therefore, the protective layer may absorb an external impact which may be applied during a process of joining the heat dissipation sheet, thereby reducing or minimizing a degree to which the backplate is dented.

### CROSS-REFERENCE TO RELATED APPLICATIONS

This application claims the priority of Korean Patent Application No. 10-2023-0197081 filed on Dec. 29, 2023, in the Korean Intellectual Property Office, the disclosure of which is incorporated herein by reference.

### BACKGROUND

### Technical Field

The present specification relates to a display device, and more particularly, to a display device capable of reducing or minimizing a degree to which an external appearance thereof is stained by being dented.

### Description of the Related Art

Recently, display panels for visually expressing electrical information signals have been rapidly developed as the information age has come in earnest. Therefore, various display devices, which are thin in thickness and light in weight and have excellent performances such as low power consumption, have been developed. A plastic organic light-emitting display device uses a plastic film as a base material instead of thick glass, and thus the plastic organic light-emitting display device has the advantage of being thin, lightweight, excellent in flexibility, and easy to apply in various shapes such as a flexible display device.

Meanwhile, the display device has a display area that substantially displays images, and a bezel area that is a non-display area that is covered by a light-blocking member or the like and does not substantially display images. Display elements for displaying images are disposed in the display area, and various lines, drive circuits, or the like for operating the display elements are disposed in the bezel area. The display device is equipped with a camera, a speaker, a microphone, various types of sensors, and the like to provide various functions, and these components are also disposed in the bezel area.

Recently, studies have been actively conducted to reduce the bezel area to beautify the design of the display device and provide a widest screen in a limited size of the display device. In order to meet this requirement, a technology is being proposed that disposes the components, such as the camera, the speaker, the microphone, and the sensor, which have been disposed in the bezel area in the related art, in the display area and disposes these components on a rear surface of the display panel so that images may be smoothly displayed.

These display devices may be applied not only to mobile devices such as smartphones and tablet PCs but also to televisions (TVs), vehicle displays, wearable devices, and the like, and the application fields for the display devices are expanding.

### BRIEF SUMMARY

Various embodiments of the present specification provide a display device capable of reducing or minimizing a degree to which a backplate is dented by an external impact.

Various embodiments of the present specification provide a display device capable of reducing or minimizing the amount of stains on an external appearance.

Various embodiments of the present specification provide a display device with improved reliability.

Technical benefits of the present disclosure are not limited to the above-mentioned benefits, and other benefits, which are not mentioned above, can be clearly understood by those skilled in the art from the following descriptions.

A display device according to an embodiment of the present specification may include: a display panel including a light transmission area having subpixels for displaying image, a backplate disposed below the display panel, a protective layer disposed below the backplate, a heat dissipation sheet disposed below the protective layer, and an optical device disposed below the display panel and configured to overlap the light transmission area, in which the protective layer and the heat dissipation sheet respectively include openings that overlap the light transmission area. Therefore, the protective layer may absorb an external impact which may be applied during a process of joining the heat dissipation sheet, thereby reducing or minimizing a degree to which the backplate is dented.

Other detailed matters of the exemplary embodiments are included in the detailed description and the drawings.

According to the embodiment of the present specification, the protective layer may absorb an external impact, thereby reducing or minimizing a degree to which the backplate is dented.

According to the embodiment of the present specification, it is possible to reduce or minimize the occurrence of stains and inhibit the stains on the external appearance of the display device from being visually recognized.

According to the embodiment of the present specification, it is possible to improve the reliability of the display device.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic configuration view of a display device according to an embodiment of the present specification;

FIG. 2 is a schematic top plan view of the display device according to the embodiment of the present specification;

FIG. 3 is a schematic rear view of the display device according to the embodiment of the present specification;

FIG. 4 is a cross-sectional view taken along line A-A′ in FIG. 3;

FIG. 5 is a cross-sectional view of a display device according to another embodiment of the present specification;

FIG. 6 is a cross-sectional view of a display device according to still another embodiment of the present specification;

FIG. 7 is a cross-sectional view of a display device according to yet another embodiment of the present specification;

FIG. 8 is a cross-sectional view illustrating a subpixel of the display device according to the embodiment of the present specification; and

FIG. 9 is a view illustrating a light-emitting element and a capping layer according to the embodiment of the present specification.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

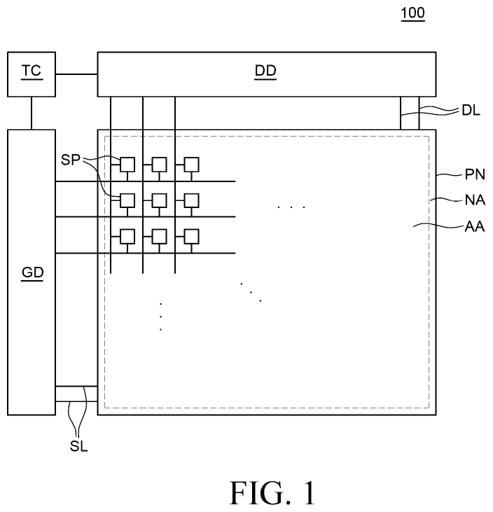

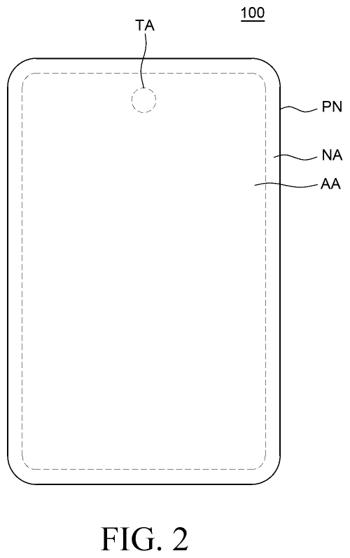

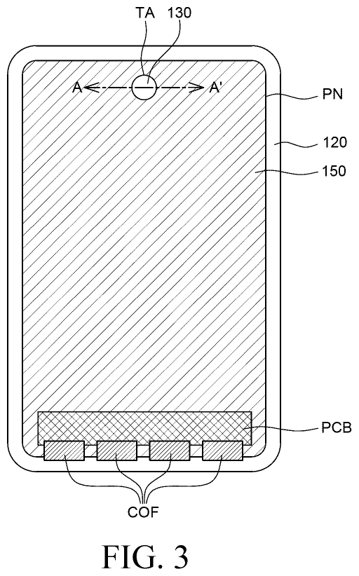

FIG. 1 is a schematic configuration view of a display device according to an embodiment of the present specification. FIG. 2 is a schematic top plan view of the display device according to the embodiment of the present specification. FIG. 3 is a schematic rear view of the display device according to the embodiment of the present specification. FIG. 1 illustrates only a display panel PN, a gate drive part GD, a data drive part DD, and a timing controller TC among various constituent elements of a display device 100, FIG. 2 illustrates only the display panel PN, and FIG. 3 illustrates only a cover glass 120, a backplate 130, a heat dissipation sheet 150, a flexible film COF, and a printed circuit board PCB. Meanwhile, in FIG. 3, for convenience of description, the cover glass 120 and the backplate 130 are not hatched.

With reference to FIG. 1, the display device 100 may include the display panel PN including a plurality of subpixels SP, the gate drive part GD and the data drive part DD configured to supply various types of signals to the display panel PN, and the timing controller TC configured to control the gate drive part GD, and the data drive part DD.

The gate drive part GD supplies a plurality of scan signals to a plurality of scan lines SL in response to a plurality of gate control signals provided from the timing controller TC. FIG. 1 illustrates that the single gate drive part GD is disposed to be spaced apart from one side of the display panel PN. However, the number and arrangement of the gate drive part GD are not limited thereto.

The data drive part DD converts image data, which are inputted from the timing controller TC, into a data voltage by using a reference gamma voltage in response to a plurality of data control signals provided from the timing controller TC. The data drive part DD may supply the converted data voltage to a plurality of data lines DL.

The timing controller TC aligns image data, which are inputted from the outside, and supplies the image data to the data drive part DD. The timing controller TC may generate the gate control signals and the data control signals by using synchronizing signals, e.g., dot clock signals, data enable signals, and horizontal/vertical synchronizing signals inputted from the outside. Further, the timing controller TC may control the gate drive part GD and the data drive part DD by supplying the generated gate control signals and data control signals to the gate drive part GD and the data drive part DD.

The display panel PN is configured to display images to a user and includes the plurality of subpixels SP. In the display panel PN, the plurality of scan lines SL, and the plurality of data lines DL intersect one another, and each of the plurality of subpixels SP is connected to the scan line SL and the data line DL. In addition, although not illustrated in the drawings, the plurality of subpixels SP may be respectively connected to a high-potential power line, a low-potential power line, a reference line, and the like.

With reference to FIGS. 1 and 2, the display panel PN may have a display area AA, and a non-display area NA configured to surround the display area AA.

The display area AA is an area of the display device 100 in which images are displayed. The display area AA may include the plurality of subpixels SP constituting a plurality of pixels, and a circuit configured to operate the plurality of subpixels SP. The plurality of subpixels SP is minimum units that constitute the display area AA. The n subpixels SP may constitute a single pixel. The plurality of subpixels SP may include a first subpixel SP_R, a second subpixel SP_G, and a third subpixel SP_B. A light-emitting element, a thin-film transistor for operating the light-emitting element, and the like may be disposed in each of the plurality of subpixels SP. A red light-emitting element, a green light-emitting element, and a blue light-emitting element may be disposed in the first subpixel SP_R, the second subpixel SP_G, and the third subpixel SP_B, respectively. However, the present disclosure is not limited thereto. The plurality of light-emitting elements may be differently defined depending on the type of the display panel PN. For example, in case that the display panel PN is an organic light-emitting display panel, the light-emitting element may be an organic light-emitting diode (OLED).

A plurality of lines for transmitting various types of signals to the plurality of subpixels SP is disposed in the display area AA. For example, the plurality of lines may include the plurality of data lines DL for supplying data voltages to the plurality of subpixels SP, and the plurality of scan lines SL for supplying scan signals to the plurality of subpixels SP. The plurality of scan lines SL may extend in one direction in the display area AA and be connected to the plurality of subpixels SP. The plurality of data lines DL may extend in a direction different from one direction in the display area AA and be connected to the plurality of subpixels SP. In addition, the low-potential power line, the high-potential power line, and the like may be further disposed in the display area AA. However, the present disclosure is not limited thereto.

The non-display area NA may be defined as an area in which no image is displayed, e.g., an area extending from the display area AA. The non-display area NA may include link lines and pad electrodes for transmitting signals to the subpixels SP in the display area AA. Alternatively, the non-display area NA may include drive ICs such as gate drivers IC and data drivers IC.

However, the non-display area NA may be positioned on a rear surface of the display panel PN, e.g., a surface on which the subpixel SP is not present. Alternatively, the non-display area NA may be excluded. However, the present disclosure is not limited to the configuration illustrated in the drawings.

Meanwhile, the drive parts such as the gate drive part GD, the data drive part DD, and the timing controller TC may be connected to the display panel PN in various ways. For example, the gate drive part GD may be mounted in the non-display area NA by a gate-in-panel (GIP) method or mounted between the plurality of subpixels SP in the display area AA by a gate-in-active area (GIA) method. For example, the data drive part DD and the timing controller TC may be formed on a separate flexible film and the printed circuit board PCB. The data drive part DD and the timing controller TC may be electrically connected to the display panel PN by bonding the flexible film and the printed circuit board PCB to the pad electrode formed in the non-display area NA of the display panel PN.

In case that the gate drive part GD is mounted by the GIP method and the data drive part DD and the timing controller TC transmit signals to the display panel PN through the pad electrode in the non-display area NA, it is necessary to ensure an area of the non-display area NA at a predetermined level or higher in order to dispose the gate drive part GD and the pad electrode, which may increase a bezel.

Alternatively, in case that the gate drive part GD is mounted in the display area AA by the GIA method and a side line, which connects a signal line on a front surface of the display panel PN to the pad electrode on the rear surface of the display panel PN, is formed to bond the flexible film and the printed circuit board to the rear surface of the display panel PN, it is possible to reduce or minimize the non-display area NA on the front surface of the display panel PN. That is, in case that the gate drive part GD, the data drive part DD, and the timing controller TC are connected to the display panel PN by the above-mentioned method, a zero bezel in which the bezel is not substantially present may be implemented.

With reference to FIGS. 2 and 3, the display device 100 may include the display panel PN, the cover glass 120, the backplate 130, and the heat dissipation sheet 150.

With reference to FIG. 2, the display area AA may include a light transmission area TA. The light transmission area TA may be an area that overlaps an optical device from a plan view. The light transmission area TA may be an area that may both display images and transmit light. That is, because the light transmission area TA is included in the display area AA, the light transmission area TA may include a structure that may transmit light and have the subpixel for displaying images. That is, it is possible to improve the light transmittance without forming a separate opening in the display panel PN. Therefore, the light transmission area TA may have a structure for improving the light transmittance. That is, a separate opening does not need to be formed in the display panel PN to improve the light transmittance. That is, in order to improve the light transmittance, the light transmission area TA may be different in subpixel arrangement structures and line arrangement structures from an area that is not the light transmission area in the display area AA. The light transmittance required to perform the function may vary depending on the type of optical device. For example, in case that the light transmittance required to perform the function of the optical device is comparatively low, such as a case in which the optical device is a sensor or the like, the light transmission area TA may be identical in subpixel arrangement structures and line arrangement structures to a portion of the display area AA that is not the light transmission area TA. That is, the subpixel arrangement structure and the line arrangement structure of the light transmission area TA may be determined depending on the type of optical device disposed in the light transmission area TA. Meanwhile, in the drawings, the light transmission area TA is illustrated as having a circular shape. However, the present disclosure is not limited thereto. The light transmission area TA may have various shapes such as a quadrangular shape, a hexagonal shape, or an octagonal shape.

Meanwhile, some constituent elements of the display device 100 may each include an opening. Specifically, some constituent elements may have openings formed at positions corresponding to the light transmission area TA so that light may pass through the openings and reach the optical device disposed below the display panel PN.

With reference to FIG. 3, the cover glass 120 may be disposed above the display panel PN. The cover glass 120 may have a shape corresponding to the display panel PN and be disposed to cover the display panel PN. The cover glass 120 may protect the display panel PN from an external impact, moisture, heat, or the like. For example, the cover glass 120 may be a tempered glass. However, the present disclosure is not limited thereto.

Meanwhile, the backplate 130 and the heat dissipation sheet 150 may be disposed below the display panel PN.

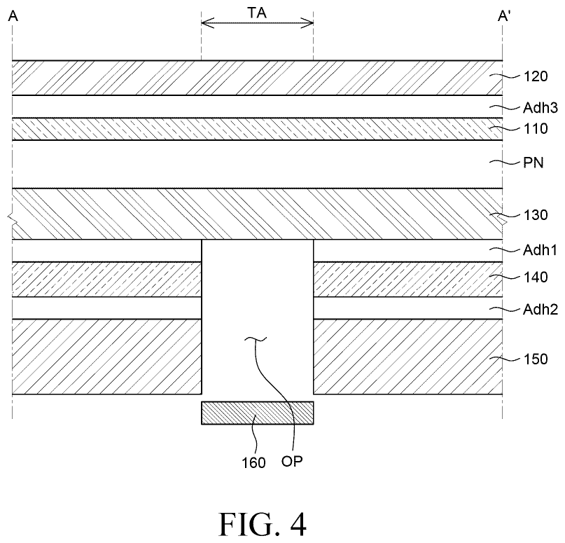

The backplate 130 may support the display panel PN and protect the display panel PN from external moisture, heat, impact, or the like. The backplate 130 may be made of a transparent organic insulating material to suppress curl and static electricity of the display device 100 and inspect an external appearance of the rear surface of the display device 100. In this case, in order to ensure transparency for light transmission, the constituent elements disposed below the backplate 130 may include openings disposed in an area that overlaps the light transmission area TA from a plan view. In contrast, the backplate 130 and the constituent elements disposed above the backplate 130 may have no opening formed in the area that overlaps the light transmission area TA from a plan view. The backplate 130 will be described below in more detail with reference to FIG. 4.

The heat dissipation sheet 150 may be disposed below the backplate 130. The heat dissipation sheet 150 may include an electrically conductive material having high thermal conductivity, such that the heat dissipation sheet 150 may simultaneously perform a heat dissipation function and a grounding function and protect the rear surface of the display panel PN. Because the heat dissipation sheet 150 is made of a metallic material, the heat dissipation sheet 150 may have an opening formed in the area, which overlaps the light transmission area TA, in order to transmit light. The heat dissipation sheet 150 will be described in more detail with reference to FIG. 4.

Meanwhile, drive components including the plurality of flexible films COF and the printed circuit board PCB may be disposed on the rear surface of the display device 100. The plurality of flexible films COF is components that supply signals to the plurality of subpixels. The plurality of flexible films COF is configured such that various types of components, such as the data driver ICs, are disposed on base films having flexibility. The printed circuit board PCB is a component electrically connected to the plurality of flexible films COF and configured to supply signals to the drive ICs. Various types of components for supplying various signals to the drive ICs may be disposed on the printed circuit board PCB.

FIG. 4 is a cross-sectional view of the display device according to the embodiment of the present specification.

With reference to FIG. 4, the display device 100 may include the cover glass 120, a third bonding layer Adh3, a polarizing layer 110, the display panel PN, the backplate 130, a first bonding layer Adh1, a protective layer 140, a second bonding layer Adh2, the heat dissipation sheet 150, and an optical device 160.

First, the display panel PN may include a substrate and light-emitting elements.

The substrate may be a support member for supporting other constituent elements disposed on the substrate of the display device 100, and the substrate may be made of an insulating material. For example, the substrate may be made of glass, resin, or the like. In addition, the substrate may include plastic such as polymer or polyimide (PI) and be made of a material having flexibility.

The light-emitting elements may be disposed on the substrate. The light-emitting elements may be differently defined depending on the type of display panel PN. For example, in case that the display panel PN is an organic light-emitting display panel, the light-emitting element may be an organic light-emitting diode (OLED).

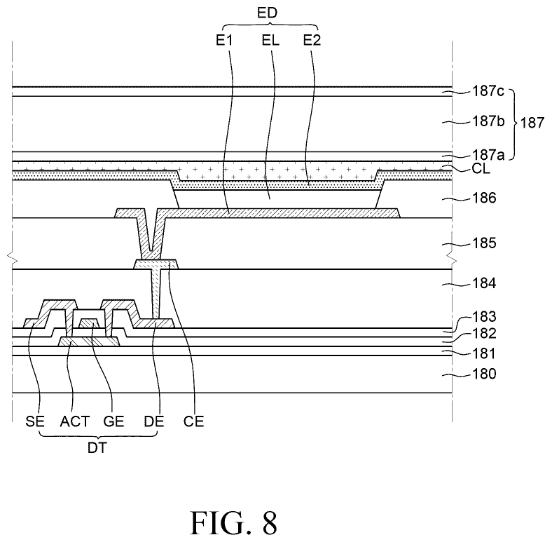

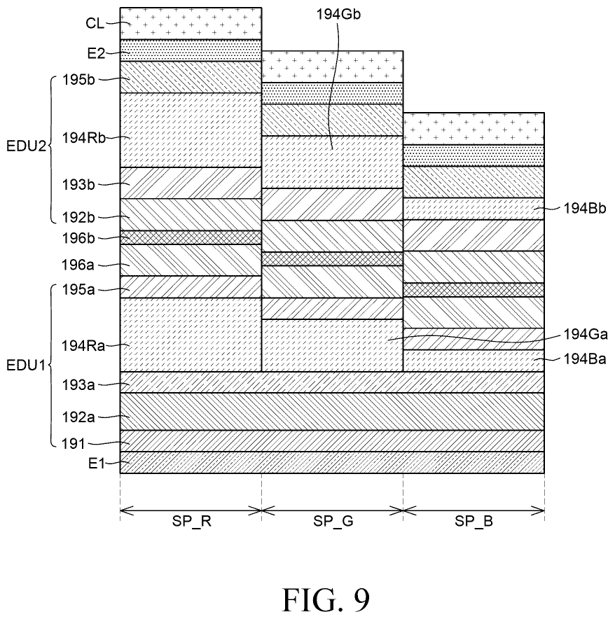

A driving transistor for operating the light-emitting element may be disposed between the substrate and the light-emitting element. The driving transistors may be respectively disposed in a plurality of subpixel areas. For example, the driving transistor may include a gate electrode, an active layer, a source electrode, and a drain electrode. In addition, the driving transistor may further include a gate insulation layer that insulates the gate electrode from the active layer, and the driving transistor may further include an interlayer insulation layer that insulates the gate electrode from the source electrode and the drain electrode. The display panel PN will be described in detail with reference to FIGS. 8 and 9.

The polarizing layer 110 may be disposed above the display panel PN. The polarizing layer 110 may be a layer for polarizing incident light. The polarizing layer 110 may include a polarizing plate that is a film having light transmittance at a predetermined level and absorbs external light and reflected light thereof to suppress a decrease in contrast ratio. That is, it is possible to suppress the deterioration in display quality caused by reflected light made when external light is reflected, and it is possible to improve an image transmittance rate of the display device 100. Meanwhile, the polarizing layer 110 may have no opening OP formed in the area that overlaps the light transmission area TA from a plan view. That is, the polarizing layer 110 may be disposed even in the area that overlaps the light transmission area TA.

The cover glass 120 may be disposed on the polarizing layer 110. The cover glass 120 may have a shape corresponding to the display panel PN and be disposed to cover the display panel PN. The cover glass 120 may protect the display panel PN from an external impact, moisture, heat, or the like. For example, the cover glass 120 may be a tempered glass. However, the present disclosure is not limited thereto.

The third bonding layer Adh3 may be disposed between the polarizing layer 110 and the cover glass 120. The third bonding layer Adh3 may fix the polarizing layer 110 and the cover glass 120. The third bonding layer Adh3 may be an optically clear adhesive (OCA) that reduces or minimizes the occurrence of foreign substances or bubbles between the polarizing layer 110 and the cover glass 120. However, the present disclosure is not limited thereto.

Meanwhile, the backplate 130 may be disposed below the display panel PN. The backplate 130 may support the display panel PN and protect the display panel PN from external moisture, heat, impact, or the like. The backplate 130 may be made of a transparent organic insulating material to suppress curl and static electricity of the display device 100 and inspect an external appearance of the rear surface of the display device 100. For example, the backplate 130 may be made of plastic such as polymethyl methacrylate (PMMA), polycarbonate (PC), polyvinyl alcohol (PVA), acrylonitrile-butadiene-styrene (ABS), polyethylene terephthalate (PET), silicone, and polyurethane (PU). However, the present disclosure is not limited thereto.

Meanwhile, a rear surface RS of the backplate 130 may be exposed through the openings OP of the constituent elements disposed below the backplate 130. Specifically, the constituent elements disposed below the backplate 130 may include the openings OP, which overlap the light transmission area TA from a plan view, to transmit light. Therefore, an area of the rear surface RS of the backplate 130, which overlaps the light transmission area TA, may be exposed.

The protective layer 140 may be disposed below the backplate 130. The protective layer 140 may protect the backplate 130 from an external impact that may be applied during a process of manufacturing the display device. Therefore, the protective layer 140 may be porous foam including a plurality of pores to improve impact resistance. However, the present disclosure is not limited thereto. For example, the protective layer 140 may be made of a material including acrylic, polyethylene, or silicone. A thickness of the protective layer 140 may be about 100 to 200 □m to perform an effective buffer function. However, the present disclosure is not limited thereto. Meanwhile, the protective layer 140 may include the opening OP disposed in the area, which overlaps the light transmission area TA from a plan view, to ensure transparency for light transmission.

The first bonding layer Adh1 may be disposed between the backplate 130 and the protective layer 140. The first bonding layer Adh1 may fix the backplate 130 and the protective layer 140. The first bonding layer Adh1 may be a pressure sensitive adhesive (PSA) that reduces or minimizes the occurrence of foreign substances or bubbles between the backplate 130 and the protective layer 140. However, the present disclosure is not limited thereto. Meanwhile, like the protective layer 140, the first bonding layer Adh1 may have the opening OP formed in the area that overlaps the light transmission area TA.

The heat dissipation sheet 150 may be disposed below the first bonding layer Adh1. The heat dissipation sheet 150 may include an electrically conductive material having high thermal conductivity, such that the heat dissipation sheet 150 may simultaneously perform a heat dissipation function and a grounding function and protect the rear surface of the display panel PN. The heat dissipation sheet 150 may be made of various electrically conductive materials, e.g., a material including aluminum (Al) or copper (Cu). However, the present disclosure is not limited thereto. A thickness of the heat dissipation sheet 150 may be about 100 to 300 □m to perform an effective heat dissipation function. However, the present disclosure is not limited thereto. Meanwhile, because the heat dissipation sheet 150 is made of a metallic material, the heat dissipation sheet 150 may have the opening OP formed in the area, which overlaps the light transmission area TA, in order to transmit light.

Meanwhile, a foam pad and a base layer may be additionally disposed below the heat dissipation sheet 150 to ensure a buffer effect and a rigidity reinforcement. However, the present disclosure is not limited thereto.

The optical device 160 may be disposed below the display panel PN. The optical device 160 may be a device that receives light having passed through the display panel PN and performs a predetermined function in response to the received light. Therefore, the optical device 160 may be disposed to overlap the light transmission area TA of the display panel PN. For example, the optical device 160 may be configured as a camera or various sensors. However, the present disclosure is not limited thereto. The optical device 160 may include all devices that perform predetermined functions in response to the light. Meanwhile, because the optical device 160 is disposed below the display panel PN, the optical device 160 may not be visually recognized by the user. For example, in case that the optical device 160 is a camera, the camera is disposed on the rear surface of the display panel PN. However, the camera may capture an image of the front surface of the display device 100 instead of the rear surface of the display device 100.

Recently, studies have been actively conducted to reduce the bezel area in order to display images in the widest area in a limited size of the display device. In order to meet this requirement, a technology is being proposed that disposes optical devices, such as cameras and various sensors, which have been disposed in the bezel area in the related art, in the display area and disposes these components on the rear surface of the display panel so that images may be smoothly displayed.

Meanwhile, in order to allow the optical device to perform a correct function, the display device needs to be designed so that the rear surface of the display panel transmits light. Therefore, unlike the constituent elements disposed above the display panel PN, the openings may be formed in the constituent elements disposed below the display panel. For example, the heat dissipation sheet may be disposed below the display panel and the backplate may be disposed to protect the display panel. In general, the heat dissipation sheet is made of a metallic material excellent in thermal conductivity. Therefore, in order to ensure transparency for light transmission, the opening may be formed in the area of the heat dissipation sheet that corresponds to the light transmission area in which the optical device is disposed. In this case, during a process of joining the soft backplate and the metallic heat dissipation sheet, the backplate may be dented by an end of the heat dissipation sheet, e.g., a portion corresponding to an end of the opening. This may cause the occurrence of stains on the external appearance of the display device and a defect of the display panel.

In the display device 100 according to the embodiment of the present specification, the opening OP may be formed in the area of the heat dissipation sheet 150, which overlaps the light transmission area TA, to transmit light to the optical device 160 disposed below the display panel PN. At the same time, the protective layer 140 may be disposed between the backplate 130 and the heat dissipation sheet 150. The protective layer 140 may have a porous structure, such that the protective layer 140 may protect the backplate 130 by absorbing an external impact that may be applied to the backplate 130 during the process. In this case, like the heat dissipation sheet 150, the protective layer 140 may also include the opening OP corresponding to the light transmission area TA. That is, in the display device 100 according to the embodiment of the present specification, the opening OP may be disposed in the heat dissipation sheet 150 to transmit light. Further, the protective layer 140 may be disposed above the heat dissipation sheet 150, thereby protecting the backplate 130 and the display panel PN from an impact that occurs during the process. Therefore, in the display device 100 according to the embodiment of the present specification, it is possible to suppress the occurrence of stains that may occur in the vicinity of the opening OP and be visually recognized by the user.

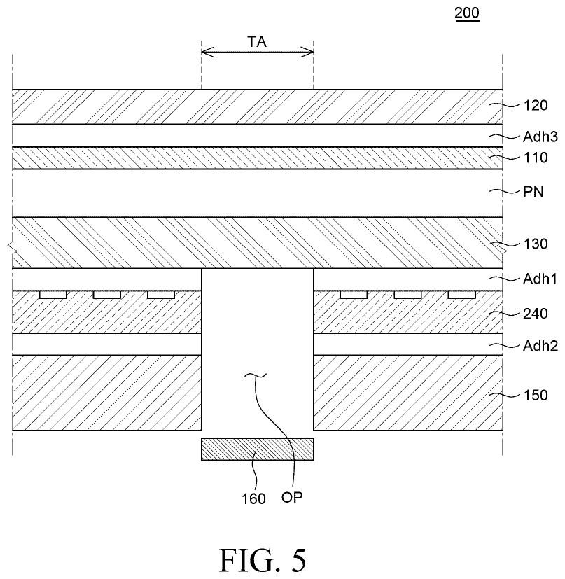

FIG. 5 is a cross-sectional view of a display device according to another embodiment of the present specification. A display device 200 in FIG. 5 is substantially identical in configuration to the display device 100 in FIGS. 1 to 4, except for a shape of a protective layer 240. Therefore, a repeated description will be omitted.

With reference to FIG. 5, the protective layer 240 may be disposed below the backplate 130. The protective layer 240 may protect the backplate 130 from an external impact that may be applied during various processes such as an assembling process. Therefore, the protective layer 240 may be porous foam including a plurality of pores to improve impact resistance. However, the present disclosure is not limited thereto. For example, the protective layer 240 may be made of a material including acrylic, polyethylene, or silicone. Meanwhile, the protective layer 240 may include the opening OP that overlaps the light transmission area TA.

In this case, one surface of the protective layer 240 may include an embossed pattern. Specifically, a top surface of the protective layer 240 may include the embossed pattern. Therefore, a top surface of the embossed pattern may adjoin the first bonding layer Adh1 disposed above the protective layer 240. A surface area of the protective layer 240 may be increased by the embossed pattern. That is, because the first bonding layer Adh1 and the protective layer 240 are pressed and brought into contact with each other, the embossed pattern may absorb an impact and reduce or minimize a lack of contact between the first bonding layer Adh1 and the protective layer 240 during the pressing process. Therefore, it is possible to inhibit bubbles from being formed between the protective layer 240 and the first bonding layer Adh1, thereby excluding a defoaming process of removing bubbles.

That is, in the display device 200 according to another embodiment of the present specification, the opening OP may be formed in the area of the heat dissipation sheet 150, which overlaps the light transmission area TA, to transmit light to the optical device 160 disposed below the display panel PN. At the same time, the protective layer 240 may be disposed between the backplate 130 and the heat dissipation sheet 150. The protective layer 240 disposed between the backplate 130 and the heat dissipation sheet 150 may have the porous structure, and one surface of the protective layer 240, which adjoins the first bonding layer Adh1, may include the embossed pattern. Therefore, it is possible to protect the backplate 130 by absorbing an external impact that may be applied to the backplate 130 during the process. Therefore, in the display device 200 according to another embodiment of the present specification, it is possible to suppress the occurrence of stains that may occur in the vicinity of the opening OP and be visually recognized by the user. In addition, a lack of contact between the first bonding layer Adh1 and the protective layer 240 may be reduced or minimized by the embossed pattern, thereby increasing a fixing force between the backplate 130 and the protective layer 240. Therefore, it is possible to more effectively protect the backplate 130 and the display panel PN.

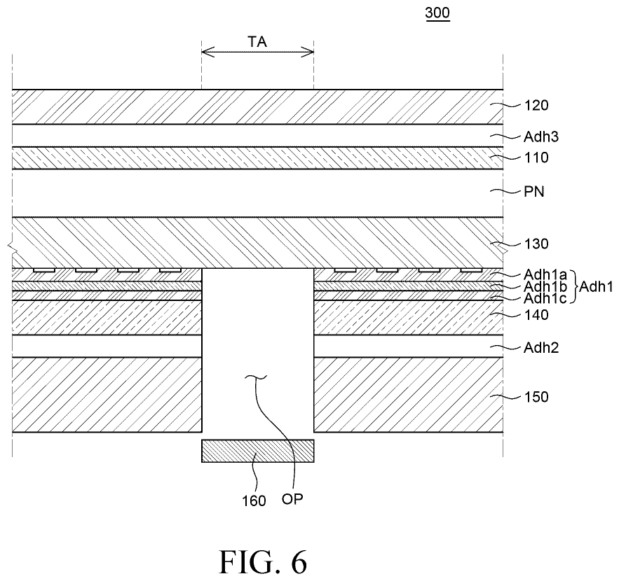

FIG. 6 is a cross-sectional view of a display device according to still another embodiment of the present specification. A display device 300 in FIG. 6 is substantially identical in configuration to the display device 100 in FIGS. 1 to 4, except for a shape of the first bonding layer Adh1. Therefore, a repeated description will be omitted.

With reference to FIG. 6, the first bonding layer Adh1 may be disposed between the backplate 130 and the protective layer 140. The first bonding layer Adh1 may be a pressure sensitive adhesive (PSA) that reduces or minimizes the occurrence of foreign substances or bubbles between the backplate 130 and the protective layer 140. However, the present disclosure is not limited thereto. Meanwhile, like the protective layer 140, the first bonding layer Adh1 may have the opening OP formed in the area, which overlaps the light transmission area TA, to transmit light.

Meanwhile, the first bonding layer Adh1 may include a base material Adh1b, a first bonding surface Adh1a disposed on a top surface of the base material Adh1b, and a second bonding surface Adh1c disposed on a bottom surface of the base material Adh1b.

The base material Adh1b of the first bonding layer Adh1 may serve to hold an overall shape of the first bonding layer Adh1. For example, the base material Adh1b may be made of a material such as polyethylene terephthalate (PET). However, the present disclosure is not limited thereto.

The second bonding surface Adh1c of the first bonding layer Adh1 may be in contact with the protective layer 140 and bond and fix the protective layer 140 to the first bonding layer Adh1.

The first bonding surface Adh1a of the first bonding layer Adh1 may be in contact with the backplate 130 and bond and fix the backplate 130 to the first bonding layer Adh1. Meanwhile, the first bonding surface Adh1a of the first bonding layer Adh1 may include an embossed pattern. Therefore, a top surface of the embossed pattern may adjoin the backplate 130 disposed above the first bonding layer Adh1. A surface area of the first bonding layer Adh1 may be increased by the embossed pattern. That is, because the first bonding layer Adh1 and the backplate 130 are pressed and brought into contact with each other, the embossed pattern may absorb an impact and reduce or minimize a lack of contact between the first bonding layer Adh1 and the backplate 130 during the pressing process. Therefore, it is possible to inhibit bubbles from being formed between the backplate 130 and the first bonding layer Adh1, thereby excluding a defoaming process of removing bubbles.

That is, in the display device 300 according to still another embodiment of the present specification, the opening OP may be formed in the area of the heat dissipation sheet 150, which overlaps the light transmission area TA, to transmit light to the optical device 160 disposed below the display panel PN. At the same time, the protective layer 140 may be disposed between the backplate 130 and the heat dissipation sheet 150. In this case, the protective layer 140 may have a porous structure, such that the protective layer 140 may protect the backplate 130 by absorbing an external impact that may be applied to the backplate 130 during the process. That is, in the display device 300 according to still another embodiment of the present specification, the opening OP may be disposed in the heat dissipation sheet 150 to transmit light. Further, the protective layer 140 may be disposed above the heat dissipation sheet 150, thereby protecting the backplate 130 and the display panel PN from an impact that occurs during the process. Therefore, in the display device 300 according to still another embodiment of the present specification, it is possible to suppress the occurrence of stains that may occur in the vicinity of the opening OP and be visually recognized by the user.

In particular, in the display device 300 according to still another embodiment of the present specification, the top surface of the first bonding layer Adh1, which bonds the backplate 130 and the protective layer 140, may include the embossed pattern. That is, an impact, which is applied during the pressing process, may be mitigated by the embossed pattern, and the surface area of the first bonding layer Adh1 may be increased, which may reduce or minimize a lack of contact between the first bonding layer Adh1 and the backplate 130. Therefore, it is possible to increase a fixing force between the backplate 130 and the protective layer 140. Therefore, it is possible to more effectively protect the backplate 130 and the display panel PN.

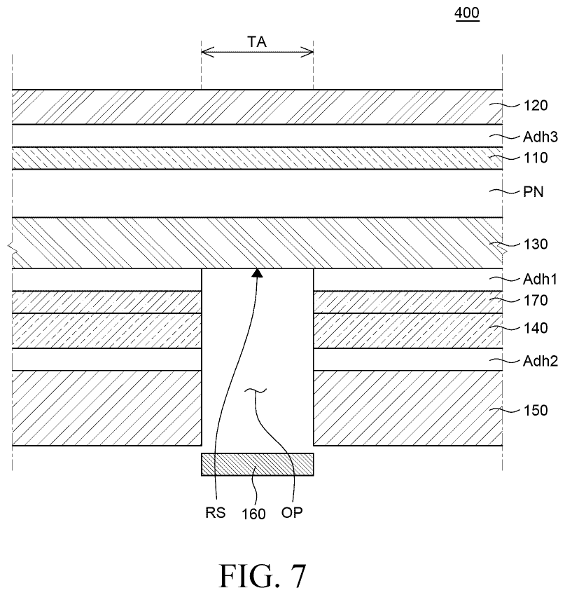

FIG. 7 is a cross-sectional view of a display device according to yet another embodiment of the present specification. A display device 400 in FIG. 7 is substantially identical in configuration to the display device 100 in FIGS. 1 to 4, except for the presence or absence of a base layer 170. Therefore, a repeated description will be omitted.

With reference to FIG. 7, the base layer 170 may be disposed between the backplate 130 and the protective layer 140. The base layer 170 may reduce or minimize the separation between the backplate 130 and the protective layer 140, perform the support function, and reinforce the rigidity. Specifically, the base layer 170 may be disposed between the protective layer 140 and the first bonding layer Adh1 disposed below the backplate 130. For example, the base layer 170 may be made of a material including polyethylene terephthalate (PET). However, the present disclosure is not limited thereto. Meanwhile, a thickness of the base layer 170 may be about 50 D m to perform the effective support function and rigidity reinforcement function. However, the present disclosure is not limited thereto. Meanwhile, the base layer 170 may also include the opening OP disposed in the area, which overlaps the light transmission area TA, to transmit light.

Meanwhile, although not illustrated in the drawings, a bonding layer may be additionally disposed between the protective layer 140 and the base layer 170 to fix the protective layer 140 and the base layer 170. However, the present disclosure is not limited to the configuration illustrated in the drawings.

That is, in the display device 400 according to yet another embodiment of the present specification, the opening OP may be formed in the area of the heat dissipation sheet 150, which overlaps the light transmission area TA, to transmit light to the optical device 160 disposed below the display panel PN. At the same time, the protective layer 140 may be disposed between the backplate 130 and the heat dissipation sheet 150. In this case, the protective layer 140 may have a porous structure, such that the protective layer 140 may protect the backplate 130 by absorbing an external impact that may be applied to the backplate 130 during the process. Therefore, in the display device 400 according to still another embodiment of the present specification, it is possible to suppress the occurrence of stains that may occur in the vicinity of the opening OP and be visually recognized by the user.

In particular, in the display device 400 according to yet another embodiment of the present specification, the base layer 170 may be additionally disposed between the backplate 130 and the protective layer 140. The base layer 170 may reduce or minimize the separation between the backplate 130 and the protective layer 140, perform the support function, and reinforce the rigidity. That is, in the display device 400 according to yet another embodiment of the present specification, the opening OP may be disposed in the heat dissipation sheet 150 to transmit light. Further, the protective layer 140 and the base layer 170 may be disposed above the heat dissipation sheet 150, thereby improving the durability and more effectively protecting the backplate 130 and the display panel PN from an impact that occurs during the process.

FIG. 8 is a cross-sectional view illustrating the subpixel of the display device according to the embodiment of the present specification. FIG. 9 is a view illustrating the light-emitting element according to the embodiment of the present specification. Specifically, FIG. 8 is a cross-sectional view illustrating one subpixel SP of the display device 100 according to the embodiment of the present specification.

With reference to FIG. 8, a substrate 180 may be a substrate, e.g., an insulation substrate configured to support the constituent elements disposed above the display device 100. The substrate 180 may be made of glass, resin, or the like. In addition, the substrate 180 may be made of a material including polymer or plastic. However, the present disclosure is not limited thereto.

A buffer layer 181 may be disposed on the substrate 180. The buffer layer 181 may reduce the penetration of moisture or impurities through the substrate 180. For example, the buffer layer 181 may be configured as a single layer or multilayer made of silicon oxide SiOx or silicon nitride SiNx. However, the present disclosure is not limited thereto. However, the buffer layer 181 may be excluded in accordance with the type of the substrate 180 or the type of thin-film transistor DT. However, the present disclosure is not limited thereto.

The transistor DT including an active layer ACT, a gate electrode GE, a source electrode SE, and a drain electrode DE may be disposed on the buffer layer 181.

First, the active layer ACT of the transistor DT may be disposed on the buffer layer 181. The active layer ACT may be made of a semiconductor material such as an oxide semiconductor, amorphous silicon, or polysilicon. However, the present disclosure is not limited thereto. In addition, although not illustrated in the drawings, in addition to the thin-film transistor DT, other transistors, such as a switching transistor, a sensing transistor, and a light emission control transistor, may be additionally disposed. The active layers of these transistors may be made of a semiconductor material such as an oxide semiconductor, amorphous silicon, or polysilicon. However, the present disclosure is not limited thereto. In addition, the active layers of the transistors, such as the thin-film transistor DT, the switching transistor, the sensing transistor, and the light emission control transistor, which are included in pixel circuits, may be made of the same material or different materials.

A gate insulation layer 182 may be disposed on the active layer ACT. The gate insulation layer 182 may be an insulation layer for electrically insulating the active layer ACT and the gate electrode GE. The gate insulation layer 182 may be configured as a single layer or multilayer made of silicon oxide SiOx or silicon nitride SiNx. However, the present disclosure is not limited thereto.

The gate electrode GE may be disposed on the gate insulation layer 182. The gate electrode GE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

An interlayer insulation layer 183 may be disposed on the gate electrode GE. The interlayer insulation layer 183 may be an insulation layer for protecting components disposed below the interlayer insulation layer 183. The interlayer insulation layer 183 may be configured as a single layer or multilayer made of silicon oxide SiOx or silicon nitride SiNx. However, the present disclosure is not limited thereto. Contact holes, through which the source electrode SE and the drain electrode DE are connected to the active layer ACT, may be formed in the interlayer insulation layer 183.

The source electrode SE and the drain electrode DE, which are electrically connected to the active layer ACT, may be disposed on the interlayer insulation layer 183. The drain electrode DE may be connected to a first electrode E1 of a light-emitting element ED through a connection electrode CE. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A first planarization layer 184 may be disposed on the source electrode SE and the drain electrode DE. The first planarization layer 184 may planarize an upper portion of the pixel circuit including the thin-film transistor DT. The first planarization layer 184 may be configured as a single layer or multilayer and made of benzocyclobutene or an acrylic-based organic material, for example. However, the present disclosure is not limited thereto. Meanwhile, a contact hole, through which the drain electrode DE is connected to the connection electrode CE, may be formed in the first planarization layer 184.

The connection electrode CE may be disposed on the first planarization layer 184. The connection electrode CE may electrically connect the drain electrode DE and the first electrode E1 of the light-emitting element ED through the contact hole formed in the first planarization layer 184.

A second planarization layer 185 may be disposed on the first planarization layer 184 and the connection electrode CE. Like the first planarization layer 184, the second planarization layer 185 may planarize the upper portion of the pixel circuit including the thin-film transistor DT. The second planarization layer 185 may be configured as a single layer or multilayer and made of benzocyclobutene or an acrylic-based organic material, for example. However, the present disclosure is not limited thereto.

With reference to FIGS. 8 and 9 together, the light-emitting element ED may be disposed on the second planarization layer 185. The light-emitting element ED may include the first electrode E1, a hole injection layer 191, a first hole transport layer 192a, a first hole adjustment layer 193a, first light-emitting layers 194Ra, 194Ga, and 194Ba, a first electron transport layer 195a, a first charge generating layer 196a, a second charge generating layer 196b, a second hole transport layer 192b, a second hole adjustment layer 193b, second light-emitting layers 194Rb, 194Gb, and 194Bb, a second electron transport layer 195b, and a second electrode E2 that are sequentially stacked.

The light-emitting element ED of the display device 100 according to the embodiment of the present specification may be an organic light-emitting element having a two-stack structure configured such that a first light-emitting unit EDU1 (1st EL Unit), which includes the first organic light-emitting layers, and a second light-emitting unit EDU2 (2nd EL Unit), which includes the second organic light-emitting layers, are stacked between the first electrode E1 and the second electrode E2. That is, the light-emitting element ED of the display device 100 according to the embodiment of the present specification may have a tandem structure.

For example, in the light-emitting element ED according to the embodiment of the present specification, the first light-emitting unit (or first light-emitting part) EDU1 may include the hole injection layer 191, the first hole transport layer 192a, the first hole adjustment layer 193a, the first organic light-emitting layers, which include a first red light-emitting layer 194Ra, a first green light-emitting layer 194Ga, and a first blue light-emitting layer 194Ba, and the first electron transport layer 195a.

In the light-emitting element ED according to the embodiment of the present specification, the second light-emitting unit (or second light-emitting part) EDU2 may include the second hole transport layer 192b, the second hole adjustment layer 193b, the second organic light-emitting layers, which include a second red light-emitting layer 194Rb, a second green light-emitting layer 194Gb, and a second blue light-emitting layer 194Bb, and the second electron transport layer 195b.

The light-emitting element ED according to the embodiment of the present specification may include the first charge generating layer 196a, e.g., an n-type charge generating layer and the second charge generating layer 196b, e.g., a p-type charge generating layer that are positioned between the first light-emitting unit EDU1 and the second light-emitting unit EDU2.

With reference to FIGS. 8 and 9, the first electrode E1 may be disposed on the second planarization layer 185. Specifically, the first electrode E1 may be disposed to correspond to the first subpixel SP_R, the second subpixel SP_G, and the third subpixel SP_B. The first electrode E1 may be a layer, e.g., an anode for supplying positive holes to the light-emitting layers EL. For example, the first electrode E1 may be made of an electrically conductive material with a high work function. The first electrode E1 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The hole injection layer 191 may be disposed on the first electrode E1 so as to correspond to all the first subpixel SP_R, the second subpixel SP_G, and the third subpixel SP_B. The hole injection layer 191 may smoothly inject the positive holes and be made of a material including any one or more of HATCN (1,4,5,8,9,11-hexaazatriphenylene-hexanitrile), CuPc (copper phthalocyanine), PEDOT (poly (3, 4)-ethylenedioxythiophene), PANI (polyaniline), and NPD (N,N-dinaphthyl-N,N′-diphenylbenzidine). However, the present disclosure is not limited thereto.

The first hole transport layer 192a and the second hole transport layer 192b may each be disposed to correspond to all the first subpixel SP_R, the second subpixel SP_G, and the third subpixel SP_B. Specifically, the first hole transport layer 192a may be disposed on the hole injection layer 191, and the second hole transport layer 192b may be disposed on the second charge generating layer 196b.

The first hole transport layer 192a and the second hole transport layer 192b may smoothly transport the positive holes and be made of any one or more of NPD (N,N-dinaphthyl-N,N′-diphenylbenzidine), TPD (N,N′-bis-(3-methylphenyl)-N,N′-bis-(phenyl)-benzidine), s-TAD, and MTDATA (4,4′,4″-Tris (N-3-methylphenyl-N-phenyl-amino)-triphenylamine). However, the present disclosure is not limited thereto.

The first hole adjustment layer 193a may be disposed on the first hole transport layer 192a so as to correspond to all the first subpixel SP_R, the second subpixel SP_G, and the third subpixel SP_B.

The second hole adjustment layer 193b may be disposed on the second hole transport layer 192b so as to correspond to the first subpixel SP_R, the second subpixel SP_G, and the third subpixel SP_B.

The first hole adjustment layer 193a and the second hole adjustment layer 193b are characterized in that the positive hole has higher mobility than the electron at a high temperature. The first hole adjustment layer 193a and the second hole adjustment layer 193b may suppress a phenomenon in which the positive holes move to the first electron transport layer 195a and the second electron transport layer 195b and depart from the light-emitting area while passing through the first organic light-emitting layers including the first red light-emitting layer 194Ra, the first green light-emitting layer 194Ga, and the first blue light-emitting layer 194Ba and the second organic light-emitting layers including a second red light-emitting layer 194Rb, the second green light-emitting layer 194Gb, and the second blue light-emitting layer 194Bb that are areas in which the electrons and the positive holes are recombined and emit light. The first hole adjustment layer 193a and the second hole adjustment layer 193b may be made of a material such as a carbazole derivative, a triarylamine derivative, a triamine derivative, or the like. For example, the first hole adjustment layer 193a and the second hole adjustment layer 193b may be made of a material including any one or more of TPD (N,N′-Bis (3-methylphenyl)-N,N′-bis (phenyl)-benzidine), α-NPB (Bis[N-(1-naphthyl)-N-phenyl]benzidine), TDAPB (1,3,5-tris (4-diphenylaminophenyl) benzene), TCTA (Tris (4-carbazoyl-9-yl) triphenylamine), spiro-TAD (2,2′,7,7′-Tetrakis (N,N-diphenylamino)-9,9-spirobifluorene), CBP (4,4′-bis(carbazol-9-yl) biphenyl), BFA-1T (4-[bis (9,9-dimethylfluoren-2-yl) amino]phenyl group), spiro-TCBz (triclabendazole), and TBA. However, the present disclosure is not limited thereto.

The first hole adjustment layer 193a and the second hole adjustment layer 193b may be made of the same material among the above-mentioned materials. Alternatively, the first hole adjustment layer 193a and the second hole adjustment layer 193b may be made of different materials among the above-mentioned materials in consideration of the mobility properties of the positive holes in the first light-emitting unit EDU1 and the second light-emitting unit EDU2.

The first red light-emitting layer 194Ra may be disposed on the first hole transport layer 192a in the first subpixel SP_R. Further, the second red light-emitting layer 194Rb may be disposed on the second hole transport layer 192b in the first subpixel SP_R. The first red light-emitting layer 194Ra and the second red light-emitting layer 194Rb may each be made of a light-emitting material that emits red light. The light-emitting material may be produced by using a phosphorescent material or a fluorescent material.

For example, the first red light-emitting layer 194Ra and the second red light-emitting layer 194Rb may include a host material made of CBP (4,4′-bis (carbozol-9-yl) biphenyl) or mCP (1,3-bis (N-carbozolyl) benzene). The first red light-emitting layer 194Ra and the second red light-emitting layer 194Rb may be made of a phosphorescent material including a dopant including any one or more of PQIr (acac) (bis(1-phenylquinoline) acetylacetonate iridium), PQIr (tris (1-phenylquinoline) iridium), and PtOEP (octaethylporphyrin platinum). Alternatively, the first red light-emitting layer 194Ra and the second red light-emitting layer 194Rb may be made of a fluorescent material including PBD:Eu (DBM) 3 (Phen) or Perylene. However, the present disclosure is not limited thereto.

The first green light-emitting layer 194Ga may be disposed on the first hole transport layer 192a in the second subpixel SP_G. Further, the second green light-emitting layer 194Gb may be disposed on the second hole transport layer 192b in the second subpixel SP_G. The first green light-emitting layer 194Ga and the second green light-emitting layer 194Gb may include a light-emitting material that emits green light. The light-emitting material may be produced by using a phosphorescent material or a fluorescent material.

For example, the first green light-emitting layer 194Ga and the second green light-emitting layer 194Gb may include a host material including CBP or mCP and be made of a phosphorescent material including a dopant material such as iridium complex (Ir complex) including Ir (ppy)3(fac-tris (2-phenylpyridine) iridium). Alternatively, the first green light-emitting layer 194Ga and the second green light-emitting layer 194Gb may be made of a fluorescent material including Alq3(tris (8-hydroxyquinolino) aluminum). However, the present disclosure is not limited thereto.

The first blue light-emitting layer 194Ba may be disposed on the first hole transport layer 192a in the third subpixel SP_B. Further, the second blue light-emitting layer 194Bb may be disposed on the second hole transport layer 192b in the third subpixel SP_B. The first blue light-emitting layer 194Ba and the second blue light-emitting layer 194Bb may include a light-emitting material that emits blue light. The light-emitting material may be produced by using a phosphorescent material or a fluorescent material.

For example, the first blue light-emitting layer 194Ba and the second blue light-emitting layer 194Bb may include a host material made of CBP or mCP and be made of a phosphorescent material including a dopant material including (4,6-F2ppy)2Irpic. However, the embodiment of the present specification is not limited thereto. In addition, the first blue light-emitting layer 194Ba and the second blue light-emitting layer 194Bb may be made of a fluorescent material including any one of spiro-DPVBi, spiro-6P, distyryl-benzene (DSB), distyryl-arylene (DSA), PFO-based polymer, and PPV-based polymer. However, the present disclosure is not limited thereto.

The first electron transport layers 195a may be disposed on the first red light-emitting layer 194Ra, the first green light-emitting layer 194Ga, and the first blue light-emitting layer 194Ba so as to correspond to all the first subpixel SP_R, the second subpixel SP_G, and the third subpixel SP_B. The second electron transport layers 195b may be disposed on the second red light-emitting layer 194Rb, the second green light-emitting layer 194Gb, and the second blue light-emitting layer 194Bb so as to correspond to all the first subpixel SP_R, the second subpixel SP_G, and the third subpixel SP_B.

The first electron transport layer 195a and the second electron transport layer 195b may transport and inject the electrons. Thicknesses of the first and second electron transport layers 195a and 195b may be adjusted in consideration of the electron transport properties. However, the present disclosure is not limited to the configuration illustrated in the drawings.

The first electron transport layer 195a and the second electron transport layer 195b may smoothly transport the electrons and be made of a material including any one or more of Alq3(tris (8-hydroxyquinolino) aluminum), PBD(2-(4-biphenylyl)-5-(4-tert-butylpheny)-1,3,4 oxadiazole), TAZ, spiro-PBD, BAlq, and SAlq. However, the present disclosure is not limited thereto.

Meanwhile, although not illustrated in the drawings, an electron injection layer EIL may be separately and additionally disposed on the second electron transport layer 195b.

The electron injection layer EIL may be made of a material including Alq3 (tris (8-hydroxyquinolino) aluminum), PBD (2-(4-biphenylyl)-5-(4-tert-butylpheny)-1,3,4 oxadiazole), TAZ, spiro-PBD, BAlq, or SAlq. However, the present disclosure is not limited thereto.

In this case, according to the embodiment of the present specification, the structures are not limited. For example, at least any one of the hole injection layer 191, the first hole transport layer 192a, the second hole transport layer 192b, the first electron transport layer 195a, the second electron transport layer 195b, and the electron injection layer EIL may be excluded. In addition, at least any one of the first hole transport layer 192a, the second hole transport layer 192b, the first electron transport layer 195a, the second electron transport layer 195b, and the electron injection layer EIL may be configured as two or more layers. The first charge generating layers 196a may be disposed on the first electron transport layers 195a so as to correspond to all the first subpixel SP_R, the second subpixel SP_G, and the third subpixel SP_B. The second charge generating layers 196b may be disposed on the first charge generating layers 196a so as to correspond to all the first subpixel SP_R, the second subpixel SP_G, and the third subpixel SP_B. The first charge generating layer 196a and the second charge generating layer 196b may be configured by an NP junction structure. However, the present disclosure is not limited thereto.

The first charge generating layer 196a and the second charge generating layer 196b may be disposed between the first light-emitting unit EDU1 and the second light-emitting unit EDU2. The first charge generating layer 196a and the second charge generating layer 196b may adjust the balance of charges between the two light-emitting units, e.g., the first light-emitting unit EDU1 and the second light-emitting unit EDU2.

The first charge generating layer 196a may serve as an n-type charge generating layer (n-CGL) that assists in injecting the electrons into the first light-emitting unit EDU1 positioned below the first charge generating layer 196a. The second charge generating layer 196b may serve as a p-type charge generating layer (p-CGL) that assists in injecting the positive holes into the second light-emitting unit EDU2 positioned above the second charge generating layer 196b.

For example, the first charge generating layer 196a, which is the n-type charge generating layer (n-CGL) that serves to inject the electrons, may be made of alkaline metal, an alkaline metal compound, an organic material, which serves to inject the electrons, or a compound thereof. However, the present disclosure is not limited thereto. In addition, the host material of the first charge generating layer 196a may be made of the same material as the material of the first electron transport layer 195a and the second electron transport layer 195b. For example, the first charge generating layer 196a may be configured as a mixed layer made by doping an organic material, such as an anthracene derivative, with a dopant such as lithium (Li). However, the present disclosure is not limited thereto.

The second charge generating layer 196b may be disposed on the first charge generating layer 196a. The second charge generating layer 196b may serve as the p-type charge generating layer (p-CGL) that serves to inject the positive holes. The host material of the second charge generating layer 196b may be made of the same material as the material of the hole injection layer 191, the first hole transport layer 192a, and the second hole transport layer 192b. However, the present disclosure is not limited thereto. For example, the second charge generating layer 196b may be configured as a mixed layer made by doping an organic material, such as HATCN (1,4,5,8,9,11-hexaazatriphenylene-hexanitrile), CuPc (cupper phthalocyanine), and TBAHA (tris (4-bromophenyl) aluminum hexacholroantimonate), with a p-type dopant. However, the present disclosure is not limited thereto. In addition, the p-type dopant may be made of a material including any one of F4-TCNQ or NDP-9. However, the present disclosure is not limited thereto.

The second electrodes E2 may be disposed on the second electron transport layers 195b so as to correspond to all the first subpixel SP_R, the second subpixel SP_G, and the third subpixel SP_B. For example, the second electrode E2 may be made of an alloy (Mg:Ag) of magnesium and silver and have semi-transmissive properties. For example, the light emitted from the organic light-emitting layer is displayed to the outside through the second electrode E2. Because the second electrode E2 has the semi-transmissive properties, a part of the light may be directed back to the first electrode E1.

As described above, the luminous efficiency increases as light is repeatedly reflected in a cavity between the first electrode E1 and the second electrode E2 by a micro-cavity effect in which the light is repeatedly reflected between the first and second electrode E1 and E2 that serve as reflective layers.

In addition, the first electrode E1 may be configured as a transmissive electrode, and the second electrode E2 may be configured as a reflective electrode, such that the light from the organic light-emitting layer may be displayed to the outside through the first electrode EL.

A capping layer CL may be disposed on the second electrode E2. The capping layer CL may improve the light extraction effect of the organic light-emitting element. The capping layer CL may be made of the same material as any one of the materials of the first hole transport layer 192a and the second hole transport layer 192b, the materials of the first electron transport layer 195a and the second electron transport layer 195b, and the host materials of the first red light-emitting layer 194Ra, the second red light-emitting layer 194Rb, the first green light-emitting layer 194Ga, the second green light-emitting layer 194Gb, the first blue light-emitting layer 194Ba, and the second blue light-emitting layer 194Bb. However, the embodiments of the present specification are not limited thereto. In addition, the capping layer CL may be excluded, as necessary.

With reference to FIG. 8, an encapsulation layer 187 may be disposed on the light-emitting element ED. The encapsulation layer 187 may protect the light-emitting element ED from external moisture, oxygen, impact, and the like. The encapsulation layer 187 may have a multilayer structure in which an inorganic layer, which is made of an inorganic insulating material, and an organic layer, which is made of an organic material, are stacked. For example, the encapsulation layer 187 may have a multilayer structure including at least one organic layer and at least two inorganic layers and made by alternately stacking the inorganic layers and the organic layer. However, the present disclosure is not limited thereto.

For example, the encapsulation layer 187 may have a three-layer structure including a first inorganic encapsulation layer 187a, an organic encapsulation layer 187b, and a second inorganic encapsulation layer 187c. In this case, the first inorganic encapsulation layer 187a and the second inorganic encapsulation layer 187c may each be independently made of a material selected from a group consisting of silicon nitride SiNx, silicon oxide SiOx, aluminum oxide AlOx, and silicon oxynitride SiON. However, the present disclosure is not limited thereto. For example, the organic encapsulation layer 187b may be made of a material selected from a group consisting of epoxy resin, polyimide resin, polyethylene resin, and silicon oxycarbide SiOC. However, the present disclosure is not limited thereto.

The exemplary embodiments of the present disclosure can also be described as follows:

According to an aspect of the present disclosure, there is provided a display device. The display device includes a display panel comprising a display area including a light transmission area, and a non-display area configured to surround the display area, a backplate disposed below the display panel, a first bonding layer disposed below the backplate, a protective layer disposed below the first bonding layer, a second bonding layer disposed below the protective layer, a heat dissipation sheet disposed below the second bonding layer and an optical device disposed below the display panel and configured to overlap the light transmission area. The first bonding layer, the protective layer, the second bonding layer, and the heat dissipation sheet respectively include openings that overlap the light transmission area.

The openings may expose a rear surface of the backplate.

One surface of the protective layer may include an embossed pattern.

A top surface of the embossed pattern may adjoin the first bonding layer.

The protective layer may be made of a material including acrylic, polyethylene, or silicone.

The protective layer may include a plurality of pores.

One surface of the first bonding layer may include an embossed pattern.

A top surface of the embossed pattern of the first bonding layer may adjoin the backplate.

The display device may further include a base layer disposed between the backplate and the protective layer.

The base layer may be made of a material including polyethylene terephthalate (PET).

The heat dissipation sheet may be made of a material including aluminum (Al) or copper (Cu).

The display panel may include a substrate, a thin-film transistor disposed on the substrate and a light-emitting element disposed on the thin-film transistor. The light-emitting element may include a first electrode, a light-emitting layer disposed on the first electrode and a second electrode disposed on the light-emitting layer.

The light-emitting layer may include a first light-emitting unit and a second light-emitting unit disposed on the first light-emitting unit.

The light-emitting element may have a tandem structure.

A transportation apparatus may include the display device. The transportation apparatus refers to any device or system designed to move people or goods from one location to another. This encompasses a wide variety of vehicles and modes of transport utilized in diverse environments. Examples include automobiles such as cars, trucks, buses, and rail transport such as trains, subways, and trams. Examples may also include air transport such as airplanes, drones, helicopters and water transport such as ships and ferries.

Although not shown, a display panel of the display device or the display device itself may be incorporated into a body of the transportation apparatus. Accordingly, the display device (or the display panel), under normal operation, is not separated or detached from the body of the transportation apparatus. However, it may be separated in instances where the display needs repair.

The body of the transportation apparatus includes a motor mounted to the body. The motor may include a combustion engine, an electric motor, or a hybrid system combining an internal combustion engine (usually fueled by gasoline or diesel) with an electric motor, or the like. Accordingly, in some embodiments, the transportation apparatus may include not only conventional fuel vehicles but also electric vehicles or other vehicles that run on clean energy.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel including a light transmission area having subpixels for displaying image;
a backplate disposed below the display panel;
a protective layer disposed below the backplate;
a heat dissipation sheet disposed below the protective layer; and
an optical device disposed below the display panel and configured to overlap the light transmission area from a plan view,
wherein the protective layer and the heat dissipation sheet respectively include openings that overlap the light transmission area from a plan view.

2. The display device of claim 1, wherein the openings are configured to expose a rear surface of the backplate.

3. The display device of claim 1, wherein the backplate includes a transparent organic insulating material.

4. The display device of claim 1, wherein the backplate is configured to cover the light transmission area.

5. The display device of claim 1, wherein the backplate has a hardness smaller than that of the heat dissipation sheet.

6. The display device of claim 1, further comprising:
a first bonding layer disposed between the backplate and the protective layer.

7. The display device of claim 6, wherein the first bonding layer includes a pressure sensitive adhesive.

8. The display device of claim 6, wherein the first bonding layer includes an opening that overlap the light transmission area from a plan view.

9. The display device of claim 6, wherein one surface of the protective layer includes an embossed pattern.

10. The display device of claim 9, wherein the embossed pattern of the protective layer adjoins the first bonding layer.

11. The display device of claim 1, wherein the protective layer includes acrylic, polyethylene, or silicone.

12. The display device of claim 1, wherein the protective layer has a porous structure.

13. The display device of claim 6, wherein one surface of the first bonding layer includes an embossed pattern.

14. The display device of claim 13, wherein the embossed pattern of the first bonding layer adjoins the backplate.

15. The display device of claim 1, further comprising:
a base layer disposed between the backplate and the protective layer.

16. The display device of claim 15, wherein the base layer includes polyethylene terephthalate (PET).

17. The display device of claim 1, wherein the heat dissipation sheet includes a metallic material.

18. The display device of claim 1, wherein the display panel comprises:
a substrate;
a thin-film transistor disposed on the substrate; and
a light-emitting element disposed on the thin-film transistor.

19. The display device of claim 18, wherein the light-emitting element has a tandem structure in which a plurality of light-emitting units are stacked.

20. A transportation apparatus comprising:
a body having a motor mounted therein;
at least one display device in the body, the at least one display device including:
a display panel including a light transmission area having subpixels for displaying image;
a backplate disposed below the display panel;
a protective layer disposed below the backplate;
a heat dissipation sheet disposed below the protective layer; and
an optical device disposed below the display panel and configured to overlap the light transmission area from a plan view,
wherein the protective layer and the heat dissipation sheet respectively include openings that overlap the light transmission area from a plan view.
